(19) United States
(12) Patent Application Publication
(10) Pub. No.: US 2022/0120447 A1
(43) Pub. Date: Apr. 21, 2022

(54) COOKING DEVICE WITH CAMERA FOR MONITORING THE COOKING CHAMBER

(71) Applicant: V-Zug AG, Zug (CH)

(72) Inventors: Clemens Herlitzius, Schindellegi (CH); Pascal Bosshard, Zürich (CH); Thomas Sterba, Sins (CH); Marc Schönenberger, Zürich (CH)

(21) Appl. No.: 17/502,318

(22) Filed: Oct. 15, 2021

(30) Foreign Application Priority Data
Oct. 19, 2020 (CH) 1343/20

(51) Int. Cl. F24C 15/00; A47J 36/32; F24C 15/32; H05K 7/20

(52) U.S. Cl. CPC F24C 15/006; A47J 36/32; A47J 27/04; H05K 7/20145; F24C 15/322

(57) ABSTRACT

A cooking device comprises a cooking chamber, an imaging camera for monitoring the cooking chamber, control electronics for controlling the cooking device, and a cooling air duct for conveying cooling air. The cooling air duct is arranged and adapted such that the cooling air flows from the camera to the control electronics.

### CROSS-REFERENCE TO RELATED APPLICATION

This application claims foreign priority benefits under 35 U.S.C. § 119 to Swiss Patent Application No. 1343/20 filed on Oct. 19, 2020, the content of which is hereby incorporated by reference in its entirety.

### TECHNICAL FIELD

The invention relates to a cooking device with a cooking chamber, an imaging camera for monitoring the cooking chamber, control electronics for controlling the cooking device, and a cooling air duct for conveying cooling air.

### BACKGROUND

It is well known to use imaging cameras in cooking devices, especially ovens. Cameras record what is happening inside the cooking chamber. The image data can be transmitted to an external display, such as a smartphone, so that from any location, it is possible to view the cooking chamber by image transmission.

The image data can also be used to control the cooking process. For example, image data assist in the automatic calculation of the volume of food to be cooked or also in tracking the browning of the food to be cooked.

### SUMMARY

The object is to provide a cooking device with a camera, in which the camera is technically advantageously integrated into the overall architecture of the cooking device.

This object is solved by the subject of the independent claim. Accordingly, a cooking device comprises a cooking chamber, an imaging camera for monitoring the cooking chamber, control electronics for controlling the cooking device, and a cooling air duct for conveying cooling air. The cooling air duct can be divided into different sections and may also be interrupted by components to be cooled.

The cooling air duct is arranged and configured such that cooling air flows from the camera to the control electronics. In other words, the control electronics are arranged downstream of the camera, i.e. the cooling air cools the camera first and only then the control electronics of the cooking device.

Cooling air is understood to be air that cools or keeps cool the operating temperature of the camera and control electronics. However, the cooling air does not have to be actively cooled. For example, air at room temperature or air that is warmer than room temperature can also be sufficient.

The control electronics of the cooking device is in particular the central control electronics, which controls different actuators, in particular heating elements, light and/or cooking chamber fan, processes display data and/or also receives signals from the user and/or sensors.

Cooling the camera and the control electronics with the same cooling air has the advantage that the cooling system in the cooking device can be designed to save as much space as possible. Cooling these two components with the same cooling air is possible because the camera needs to be cooled to about 50° C. to 60° C. and the control electronics only to 70° C. to 80° C. That is, the cooling air already heated by the camera is still cool enough to cool the control electronics.

In particular, the cooking device is an oven, a microwave, a steamer or a combi oven. A combi oven combines the functions of at least two of said cooking devices.

In a particular embodiment, when the cooking device is positioned as intended, for example on a table or in a kitchenette, the camera is arranged at least partially, in particular completely, above the cooking chamber, and/or arranged at least partially, in particular completely, in front of the cooking chamber, and/or arranged directly above and/or directly to the side of the front third of the cooking chamber.

“When the cooking device is positioned as intended” means that the cooking device is mounted vertically and horizontally as intended by the manufacturer. This means, for example, that the text shown on a display can be read during normal operation, that the cooking chamber door can be opened to the front and downward, and/or, for example, that the standing feet of a freestanding cooking device are on the floor.

If the camera is located at least partially “above” the cooking chamber, this means that at least part of the camera must be located vertically further up than the ceiling of the cooking chamber. However, the camera does not have to be arranged directly above the cooking chamber ceiling, but can also overlap sideways over the cooking chamber. I.e. “above” is only a definition of a vertical and not also a lateral alignment.

The same applies to a camera that is at least partially positioned “in front” of the cooking chamber. This is only an indication in the horizontal direction. Thus, a camera can be arranged at least partially above and in front of the cooking chamber at the same time. In order for the camera to be able to see into the cooking chamber in this case, it is likely to be arranged at the upper front edge of the cooking chamber.

If, for example, the camera is arranged “directly above” the cooking chamber, this not only restricts positioning in the vertical direction, but also in the horizontal direction. In this case, i.e. in the case of an arrangement “directly above”, the camera is arranged at least partially behind the front upper edge of the cooking chamber.

The positioning of the camera in the front area of the cooking device has the advantage that only the cooking chamber itself can be viewed. It is not possible, for example, to look through the window of the door of the cooking chamber into the kitchen space. A good level of data protection is therefore guaranteed. Of course, this is not the case if the camera is located on the door itself and moves along when the door is opened.

If the camera is positioned at the top and relatively far in the front on the cooking chamber, a very good overview of the cooking chamber is possible. I.e. the three-dimensional shape of the cooking goods arranged in the cooking chamber can be captured very well by the camera.

In particular, the cooking chamber has a cuboid shape and, in particular, the camera is arranged at an upper, front corner of the cuboid-shaped cooking chamber.

The arrangement of the camera near an edge of the cooking chamber has the advantage that it absorbs as little heat as possible from the cooking chamber, because the contact surfaces with the cooking chamber are kept as small as possible. In addition, the risk of the camera becoming soiled by splashing food inside the cooking chamber is also relatively small. The danger is even smaller if the camera is located in a corner of the cooking chamber.

Advantageously, the cooling air duct is designed in such a way that it has no deflections between the camera and the control electronics. This means that the cooling air can be guided as efficiently as possible within the cooking device and the arrangement of the components to be cooled can also be kept as simple as possible.

In particular, the cooking device comprises only exactly one imaging camera. With a single camera, the interior of the cooking chamber can already be very well recorded, so that the installation of further cameras, which incur costs and would also have to be cooled, is not necessary.

Advantageously, a fan for conveying the cooling air is arranged downstream of the camera, i.e. in the cooling air duct. This measure also permits a compact design of the cooling devices.

In a preferred embodiment, the cooling air duct is oriented in the same direction in a section immediately before the camera, i.e. upstream of the camera, and in a section between the camera and the control electronics. That is, immediately upstream of the camera and between the camera and the control electronics, the cooling air flows in the same direction. As a result, the number of deflections in the cooling air duct can be kept to a minimum and there is no unnecessarily high flow resistance in the cooling system.

In particular, the cooling air duct immediately downstream of the control electronics is oriented in the same direction as the cooling air duct upstream of the control electronics.

Advantageously, the cooking device has a suction opening for sucking in cooling air from a gap between the cooking device and the built-in niche when the cooking device is installed. The suction opening is located at the side of the cooking chamber and at the same height as the camera. This allows the cooling air to flow from the gap between the cooking device and the built-in niche to the camera via the shortest possible path.

In a special embodiment, the suction opening, the camera and the control electronics are arranged in a straight line. This means that the cooling air only needs to flow over the shortest possible path between the individual components, i.e. at least between the suction opening, camera and control electronics.

In particular, the suction opening is arranged a maximum of 15 cm, in particular a maximum of 10 cm, in particular a maximum of 5 cm, upstream of the camera. This means that the cooling air flows within the cooking device only over a very short distance before it reaches the component to be cooled.

Advantageously, the camera is centered between the left and right side walls. The camera thus looks into the center of the cooking chamber from above.

In particular, control electronics are arranged above or behind the camera.

Advantageously, the cooling air duct is arranged and designed in such a way that the cooling air between the camera and the control electronics does not cool any other components to be cooled.

### BRIEF DESCRIPTION OF THE DRAWINGS

Further embodiments, advantages and applications of the invention result from the dependent claims and from the following description on the basis of the figures. The figures show:

FIG. 1 a cooking device with a camera;

FIG. 2a the cooking device of FIG. 1 in a sectional view from the front;

FIG. 2b the cooking device of FIG. 1 in a sectional view from above;

FIG. 2c the cooking device of FIG. 1 in a sectional view from the left;

FIG. 3a a cooking device with an alternative arrangement of the camera in a sectional view from the front; and

FIG. 3b the cooking device of FIG. 3a in a sectional view from the left.

### DETAILED DESCRIPTION

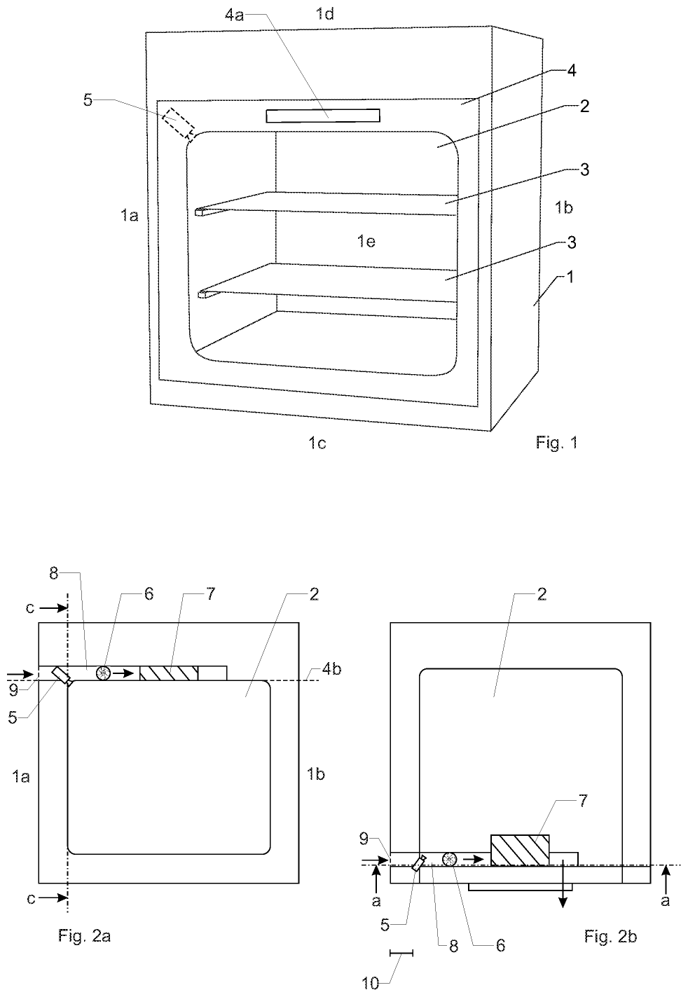

FIG. 1 shows a household cooking device with a view from the outside to the front. The cooking device comprises a housing 1 and a cooking chamber 2 arranged in the housing 1. One or more food supports 3 are arranged in the cooking chamber 2. The food supports 3 can be designed, for example, as grids, trays or the like. The cooking chamber 2 is closed on five sides, as is usually the case for household cooking devices, and is accessible to the user via a door 4. The door 4 comprises a door handle 4a with which the door 4 can be opened by hand. The cooking chamber 2 extends in depth from the rear of the cooking chamber 2 to the inside of the door 4.

The cooking device is shown as it is oriented during normal use. That is, reference numeral 1a is shown on the left, reference numeral 1b is shown on the right, reference numeral 1c is shown on the bottom, and reference numeral 1d is shown on the top of the cooking device. Reference numeral 1e marks the back of the cooking chamber. At the front of the cooking device, the door 4 is arranged.

The cooking device comprises an imaging camera 5 for monitoring the cooking chamber. It is only schematically drawn with dashed lines, as it is not visible from the outside. The camera 5 is arranged in the cuboid cooking chamber 2 at the front, left, upper corner.

FIGS. 2a to 2c show sectional views. The sectional view of FIG. 2a is a view from the front. The section line is marked with a-a in FIG. 2b. The sectional view of FIG. 2b is a view from above. The section line is marked with b-b in FIG. 2c. The sectional view of FIG. 2c is a view from the left. The section line is marked c-c in FIG. 2a. FIGS. 2a to 2c are schematic and show only the cooking chamber 2, the camera 5, a fan 6, control electronics 7, a cooling air duct 8 and a suction opening 9.

In FIG. 2a it is visible that the camera 5 is arranged partially above the cooking chamber 2, i.e. above the dashed line 4b. In close proximity to the camera 5, the cooking device comprises a suction opening 9 in the housing 1. This allows cool air, e.g. at room temperature, to flow into the cooking device from outside the cooking device in the direction of the arrow. If the cooking device is mounted in a built-in niche, the cooling air flows into the cooking device from a gap between the cooking device and the niche.

Immediately after entering the cooking device through the suction opening 9, the cooling air reaches the camera 5 to cool it. The cooling is to ensure that the camera 5 remains below a temperature between 50° C. to 60° C. Downstream of the camera 5, the cooling air flows to the control electronics 7, cools the control electronics 7 to temperatures of no more than 70° C. to 80° C. and then exits the cooking device to the front.

The cooling air duct 8 extends from the suction opening 9 to the control electronics 7 in a straight line, i.e. the cooling air flows in the same direction in the cooling air duct section between the suction opening 9 and the camera 5 as in the cooling air duct section between the camera 5 and the control electronics 7. This design and arrangement of the cooling air duct 8, the suction opening 9, the camera 5 and the control electronics 7 permits compact and simple cooling. The straight extension of the cooling air duct 8 only concerns the supply and discharge of cooling air to the camera 5 and control electronics 7. Of course, it is possible that the cooling air is redirected within the camera 5 or within the control electronics 7 for cooling these components.

It should be mentioned that the fan 6, which conveys the cooling air within the cooling air duct 8, is arranged between the camera 5 and the control electronics 7.

FIG. 2b shows the cooking device from above. Here, too, it is visible how the cooling air flows into the cooking device from the left through the suction opening 9. The camera 5 and the control electronics 7 are cooled in a direct line, since the cooling air duct from the suction opening 9 to the control electronics 7 has no deflections. Downstream of the control electronics 7, the cooling air is deflected and the cooling air leaves the cooking device to the front of the device.

To keep the distances short, the suction opening 9 is arranged very close to the camera 5. The distance between the camera 5 and the suction opening 9 is marked with the distance mark 10. This distance is about 5 cm long, i.e. the suction opening 9 is arranged about 5 cm upstream of the camera 5.

FIG. 2c shows the cooking device as seen from the left. It is visible how the camera 5 is arranged far in front at least partially above the cooking chamber 2. It is located at least partially directly above the foremost third 2a of the cooking chamber 2.

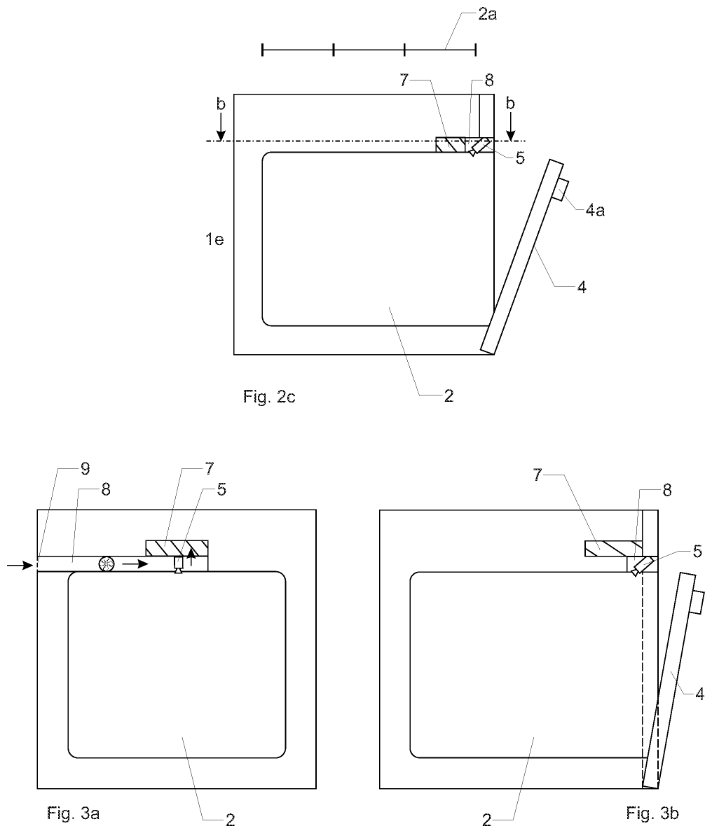

In FIGS. 3a and 3b, a second embodiment is shown. Here, the camera 5 is arranged at the upper front edge of the cooking chamber 2 in the center. As visible in FIG. 3b, the camera 5 is arranged at least partially in front of the cooking chamber, i.e. partially between the cooking chamber and the front side.

The second embodiment is illustrated with a view from the front in FIG. 3a and a view from the left in FIG. 3b. In this embodiment, the control electronics 7 are arranged above the camera 5. The cooling air flows into the cooking device through the suction opening 9, reaches the camera 5, is then deflected upwards by 90° and then reaches the control electronics 7.

While preferred embodiments of the invention are described in the present application, it should be clearly noted that the invention is not limited to these and may also be carried out in other ways within the scope of the following claims.

What is claimed is:

1. A cooking device comprising
a cooking chamber,
an imaging camera for monitoring the cooking chamber,
control electronics for controlling the cooking device,
a cooling air duct for conveying cooling air,
wherein the cooling air duct is arranged and adapted such that the cooling air flows from the camera to the control electronics.

2. The cooking device according to claim 1, wherein, when the cooking device is positioned as intended, the camera,
is arranged at least partially above the cooking chamber, and/or is arranged at least partially in front of the cooking chamber, or
is arranged at least partially directly above and/or directly to the side of the front third of the cooking chamber.

3. The cooking device according to claim 2, wherein, when the cooking device is positioned as intended, the camera is arranged completely above the cooking chamber, and/or completely in front of the cooking chamber.

4. The cooking device according to claim 1, wherein the cooling air duct is adapted such that it has no deflections between the camera and the control electronics.

5. The cooking device according to claim 1, wherein the cooking device comprises only exactly one of the camera.

6. The cooking device according to claim 1, comprising a fan for conveying the cooling air, wherein the fan is arranged downstream of the camera.

7. The cooking device according to claim 1, wherein the cooling air duct is aligned in the same direction in a section directly in front of the camera and in a section between the camera and the control electronics.

8. The cooking device according to claim 7, wherein the cooling air duct is aligned in the same direction immediately after the control electronics.

9. The cooking device according to claim 1, wherein the cooking device has a suction opening for sucking in the cooling air from a gap between the cooking device and the built-in niche when the cooking device is installed.

10. The cooking device according to claim 9, wherein the suction opening is arranged at the side of the cooking chamber at the same height as the camera.

11. The cooking device according to claim 9, wherein the suction opening, the camera and the control electronics are arranged in a straight line.

12. The cooking device according to claim 9, wherein the suction opening is arranged a maximum of 15 cm, in particular a maximum of 10 cm, in particular a maximum of 5 cm, in front of the camera in the direction of flow.

13. The cooking device according to claim 1, wherein the camera is arranged centrally between the left and right side walls of the cooking chamber.

14. The cooking device according to claim 1, wherein the control electronics are arranged above or behind the camera.

15. The cooking device according to claim 1, wherein the cooling air duct is arranged and adapted such that the cooling air between the camera and the control electronics does not cool any other components to be cooled.
